(19) United States
(12) Patent Application Publication
(10) Pub. No.: US 2007/0205458 A1
(43) Pub. Date: Sep. 6, 2007

(54) Non-Volatile Semiconductor Memory and Manufacturing Process Thereof

(76) Inventors: Satoshi Yamamoto, Tokyo (JP); Tatsunori Kaneoka, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/681,209

(22) Filed: Mar. 2, 2007

(30) Foreign Application Priority Data
Mar. 2, 2006 (JP) 2006-56284

(51) Int. Cl. H01L 29/788

(52) U.S. Cl. 257/315

(57) ABSTRACT

A non-volatile semiconductor memory which can suppress a leak current, improve dielectric strength and ensure large capacitance between a control gate and a floating gate and a manufacturing process thereof. A silicon nitride film is formed on the floating gate electrode layer of a memory cell and has a thickness of 5 nm or more. A high dielectric constant thin film is formed on the silicon nitride film. A control gate electrode layer is formed over the high dielectric constant thin film.

### CROSS-REFERENCE TO RELATED APPLICATION

The present application claims priority from Japanese patent application No. 2006-56284 filed on Mar. 2, 2006, the content of which is hereby incorporated by reference into this application.

### BACKGROUND OF THE INVENTION

The present invention relates to a non-volatile semiconductor memory and a manufacturing process thereof. Specifically, it relates to a non-volatile semiconductor memory having a floating gate electrode layer and a control gate electrode layer and a manufacturing process thereof.

The memory cell array of a non-volatile semiconductor memory may have a double-layer gate structure consisting of a control gate which is an ordinary gate and a floating gate which is electrically insulated from the surroundings. A high dielectric constant thin film such as HfO2 (hafnium oxide) may be used as an inter-gate insulating layer for insulating the control gate from the floating gate so as to increase capacitance.

Technology for using the high dielectric constant thin film as the inter-gate insulating layer is disclosed by Japanese Unexamined Patent Publication Nos. Hei 5 (1993)-129625, Hei 11(1999)-260938, 2005-26590 and Hei 6(1994)275840.

### SUMMARY OF THE INVENTION

However, when a high dielectric constant thin film is simply used as the inter-gate insulating layer, the memory retention properties of a non-volatile semiconductor memory deteriorate due to a large leak current which is generated when an electric field is applied between the control gate and the floating gate.

When a silicon oxide film is formed between the high dielectric constant thin film and the floating gate like Japanese Unexamined Patent Publication No. Hei 5(1993)-129625 and Japanese Unexamined Patent Publication No. Hei 11 (1999)-260938, dielectric strength between the control gate and the floating gate becomes low.

When a thin silicon nitride film is simply formed between the high dielectric constant thin film and the floating gate like Japanese Unexamined Patent Publication No. 2005-26590, dielectric strength between the control gate and the floating gate cannot be improved.

Further, when a silicon oxide film and a silicon nitride film are formed between the high dielectric constant thin film and the floating gate like Japanese Unexamined Patent Publication No. Hei 6(1994)-275840, the interval between the control gate and the floating gate becomes large, making it difficult to ensure large capacitance between the control gate and the floating gate.

It is an object of the present invention which has been made to solve the above problems to provide a non-volatile semiconductor memory which can suppress a leak current, improve dielectric strength and ensure large capacitance between the control gate and the floating gate and a manufacturing process thereof.

The non-volatile semiconductor memory of the present invention comprises a substrate, a floating gate electrode layer, a silicon nitride film, a high dielectric constant thin film and a control gate electrode layer. The floating gate electrode layer is formed over the substrate. The silicon nitride film is formed on the floating gate electrode layer and has a thickness of 5 nm or more. The high dielectric constant thin film is formed on the silicon nitride film. The control gate electrode layer is formed over the high dielectric constant thin film.

The process of manufacturing the non-volatile semiconductor memory of the present invention comprises the steps of: forming a floating gate conductive layer over a substrate; forming a silicon nitride film having a thickness of 5 nm or more on the floating gate conductive layer by thermal CVD; forming a high dielectric constant thin film on the silicon nitride film; and forming a control gate conductive layer over the high dielectric constant thin film.

According to the non-volatile semiconductor memory and manufacturing process thereof of the present invention, since the high dielectric constant thin film is formed between the floating gate electrode layer and the control gate electrode layer, capacitance between the floating gate electrode layer and the control gate electrode layer can be improved.

Since the silicon nitride film is formed between the floating gate electrode layer and the high dielectric constant thin film, a leak current into the floating gate electrode layer can be prevented and the memory storage properties of the non-volatile semiconductor memory can be improved. Since the silicon nitride film has a thickness of 5 nm or more, dielectric strength between the floating gate electrode layer and the control gate electrode layer can be improved.

Since the silicon nitride film is formed on the floating gate electrode layer and there is no useless layer between the silicon nitride film and the floating gate electrode layer, the interval between the floating gate electrode layer and the control gate electrode layer can be made small. Thereby, large capacitance between the floating gate electrode layer and the control gate electrode layer can be ensured.

### BRIEF DESCRIPTION OF THE DRAWINGS

FIG. 1 is a diagram showing the typical circuit configuration of a NAND type flash memory as a non-volatile semiconductor memory according to an embodiment of the present invention;

FIG. 2 is a schematic plan view showing the plan layout of the inside of the memory cell array of the NAND type flash memory as the non-volatile semiconductor memory according to the embodiment of the present invention;

FIG. 3 is a schematic sectional view cut on line III-III of FIG. 2;

FIG. 4 is a schematic sectional view cut on line IV-IV of FIG. 2;

FIGS. 5(a) and 5(b) are schematic sectional views showing a first step in the process of manufacturing a non-volatile semiconductor memory according to an embodiment of the present invention;

FIGS. 6(a) and 6(b) are schematic sectional views showing a second step in the process of manufacturing a non-volatile semiconductor memory according to the embodiment of the present invention;

FIGS. 7(a) and 7(b) are schematic sectional views showing a third step in the process of manufacturing a non-volatile semiconductor memory according to the embodiment of the present invention;

FIGS. 8(a) and 8(b) are schematic sectional views showing a fourth step in the process of manufacturing a non-volatile semiconductor memory according to the embodiment of the present invention;

FIGS. 9(a) and 9(b) are schematic sectional views showing a fifth step in the process of manufacturing a non-volatile semiconductor memory according to the embodiment of the present invention;

FIGS. 10(a) and 10(b) are schematic sectional views showing a sixth step in the process of manufacturing a non-volatile semiconductor memory according to the embodiment of the present invention;

FIGS. 11(a) and 11(b) are schematic sectional views showing a seventh step in the process of manufacturing a non-volatile semiconductor memory according to the embodiment of the present invention;

FIGS. 12(a) and 12(b) are schematic sectional views showing an eighth step in the process of manufacturing a non-volatile semiconductor memory according to the embodiment of the present invention;

FIG. 13 is a diagram showing the measurement of CVS-TDDB characteristics;

FIG. 14 is a diagram showing the measurement results of CVS-TDDB characteristics; and

FIG. 15 is a schematic sectional view in which the insulating layer between the high dielectric constant thin film and the control gate electrode layer is omitted.

### DETAILED DESCRIPTION OF THE PREFERRED EMBODIMENTS

Preferred embodiments of the present invention will be described hereinbelow with reference to the accompanying drawings.

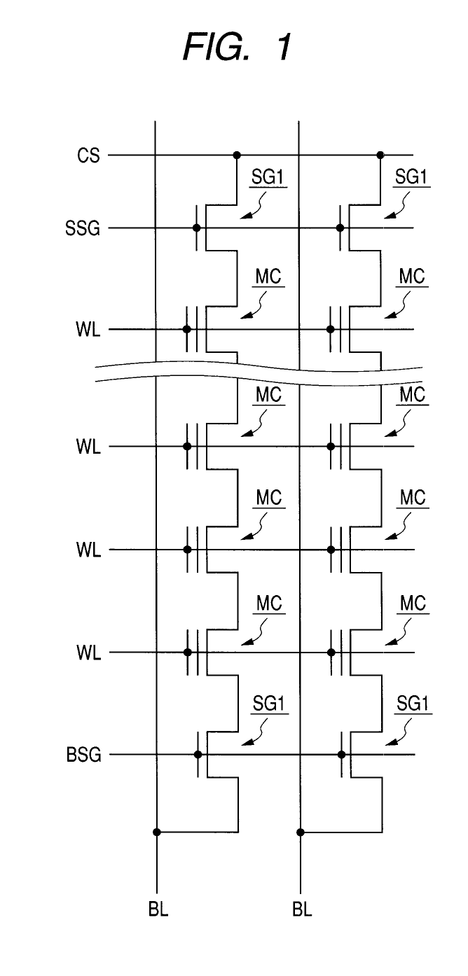

FIG. 1 is a diagram showing the typical circuit configuration of a NAND type flash memory as a non-volatile semiconductor memory according to an embodiment of the present invention. In this embodiment, a NAND type memory will be described. It is needless to say that the present invention is not limited thereto and may be applied to AND, OR, NOR and DINOR types of non-volatile semiconductor memories.

With reference to FIG. 1, in the memory cell array of the NAND type flash memory, a plurality of memory cells MC are arranged in a matrix. The control gates of memory cells MC arranged in a row direction (horizontal direction in the figure) are connected to word lines WL extending in the row direction.

A plurality of memory cells MC arranged in a column direction (longitudinal direction in the figure) are connected to one another in series. Bit line side selection transistors SG1 are connected to one ends of the memory cells MC connected in series and source line side selection transistors SG2 are connected to the other ends of the memory cells MC. The sources of the bit line side selection transistors SG1 are connected to bit lines BL which are data lines and the sources of the source line side selection transistors SG2 are connected to a common source line CS.

The gates of the bit line side selection transistors SG1 arranged in the row direction are connected to a bit line side selection gate line BSG extending in the row direction. The gates of the source line side selection transistors SG2 arranged in the row direction are connected to a source line side selection gate line SSG extending in the row direction.

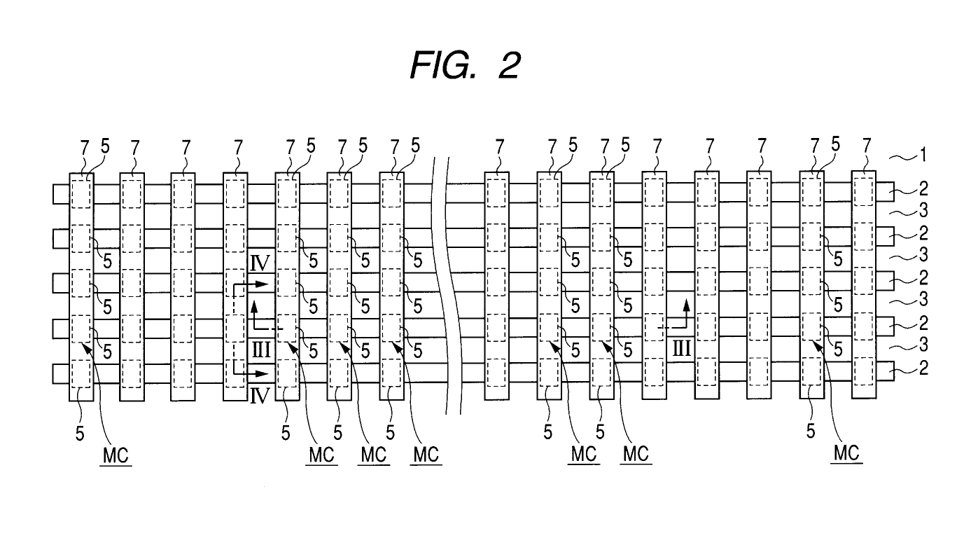

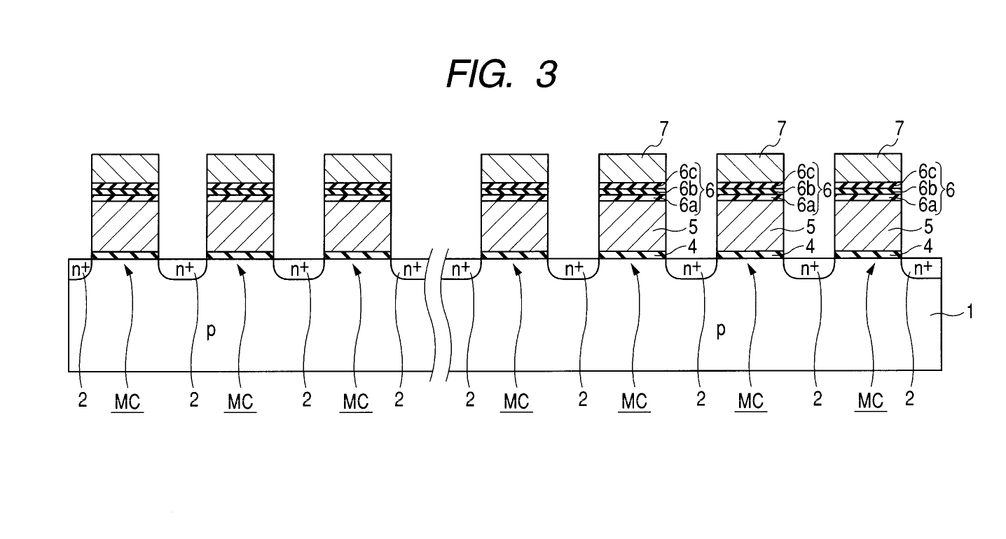

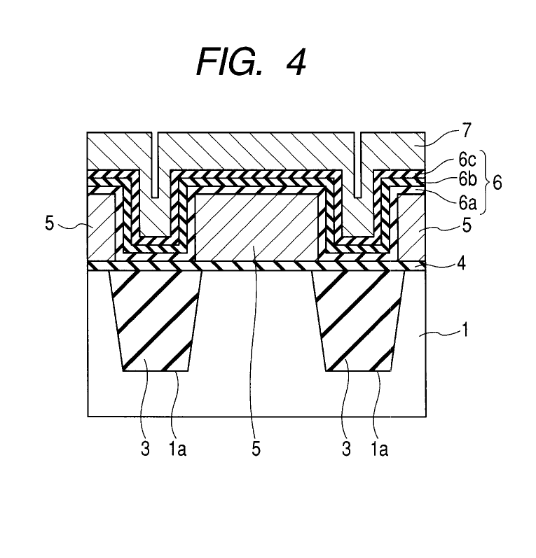

FIG. 2 is a schematic plan view showing the plan layout of the inside of the memory array of the NAND type flash memory as the non-volatile semiconductor memory according to the embodiment of the present invention. FIG. 3 is a schematic sectional view cut along line III-III of FIG. 2, and FIG. 4 is a schematic sectional view cut on line IV-IV of FIG. 2.

With reference mainly to FIG. 2, a plurality of memory cells MC are arranged in a matrix on the surface of a p type semiconductor substrate 1 made of silicon, for example. The word lines 7 integrated with the control gate electrode layers of the memory cells MC extend in the row direction (longitudinal direction in the figure). Active areas in which the source/drain areas 2 of the memory cells MC are formed exist in the column direction (horizontal direction in the figure).

With reference mainly to FIG. 4, grooves 1a are formed in the front surface of the semiconductor wafer 1, and a buried insulating layer 3 is filled in the grooves 1a. The groove 1a and the buried insulating layer 3 constitute STI (shallow trench isolation). Each active area of the semiconductor substrate 1 is surrounded by this STI.

With reference mainly to FIG. 3, each of the memory cells MC has a pair of n type source/drain area 2, a gate insulating layer 4, a floating gate electrode layer 5, an inter-gate insulating layer 6 and a control gate electrode layer 7. The pair of source/drain areas 2 are spaced apart from each other and formed on the surfaces of the active areas. The floating gate electrode layer 5 is positioned over the area sandwiched between the pair of source/drain areas 2 through the gate insulating layer 4. The control gate electrode layer 7 is formed over the floating gate electrode layer 5 through the inter-gate insulating layer 6.

The inter-gate insulating layer 6 has a silicon nitride film 6a, a high dielectric constant thin film 6b and an insulating layer 6c. The silicon nitride film 6a is formed on the floating gate electrode layer 5 and has a thickness of 5 nm or more. The high dielectric constant thin film 6b is formed on the silicon nitride film 6a. The insulating layer 6c is formed between the high dielectric constant thin film 6b and the control gate electrode layer 7 and has a larger band gap than that of the high dielectric constant thin film 6b.

The high dielectric constant thin film in this text is a thin film having a dielectric constant of 10 or more. More specifically, it contains HfO2, Al2O3 (alumina), Y2O3 (yttrium oxide), MgO (magnesium oxide), Ta2O5 (tantalum oxide), Bi2O3 (bismuth oxide), BaMgF4 (barium magnesium fluoride), HfAlO (hafnium aluminate), SrTiO3 (strontium titanate), PbTiO3 (lead titanate), BaTiO3 (barium titanate), BaSrTiO3 (barium strontium titanate), BSN (barium strontium niobate), PZT (lead zirconate titanate) or PLZT (lanthanum lead zirconate titanate) alone, or a combination thereof.

The insulating layer 6c and the gate insulating layer 4 may be, for example, a silicon oxide film or silicon nitride film, or a combination of a silicon oxide film and a silicon nitride film. The floating gate electrode layer 5 and the control gate electrode layer 7 are each made of polycrystal silicon doped with an impurity (to be referred to as “doped polysilicon” hereinafter).

A description is subsequently given of a process of manufacturing the non-volatile semiconductor memory according to this embodiment.

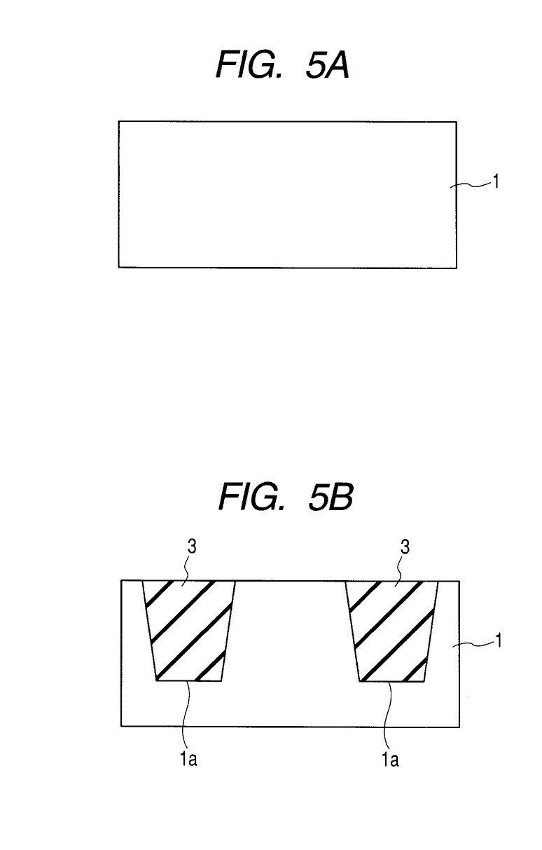

FIGS. 5 to 12 are schematic sectional views showing the process of manufacturing the non-volatile semiconductor memory in the order of its steps. FIG. 5(a) to FIG. 12(a) are sectional views cut along line III-III of FIG. 2, and FIGS. 5(b) to 12(b) are sectional views cut along line IV-IV of FIG. 2.

With reference to FIGS. 5(a) and 5(b), after the grooves 1a are selectively formed in the surface of the p type silicon substrate 1, the buried insulating layer 3 is formed to fill the grooves 1a. The groove 1a and the buried insulating layer 3 form STI for separating an active area.

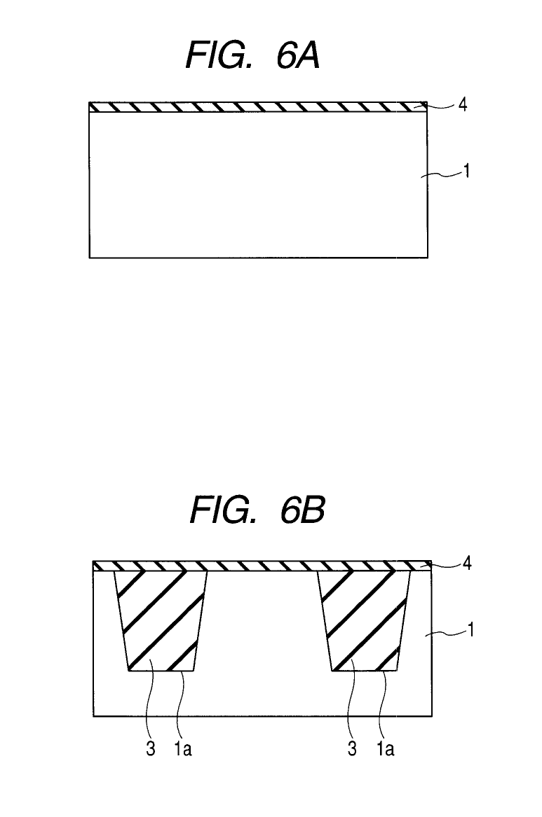

With FIGS. 6(a) and 6(b), a silicon oxide film having a thickness of 9 nm is formed as the gate insulating layer 4 on the surfaces of the active areas of the p type silicon substrate 1 by thermal oxidation.

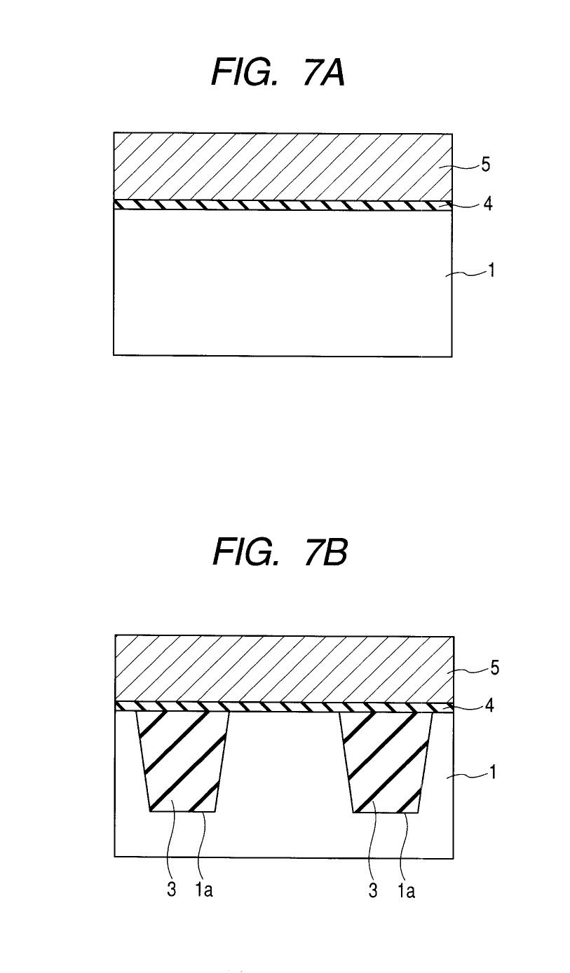

With reference to FIGS. 7(a) and 7(b), a doped polysilicon layer is formed as the floating gate conductive layer 5 on the gate insulating layer 4 by vacuum CVD (Chemical Vapor Deposition).

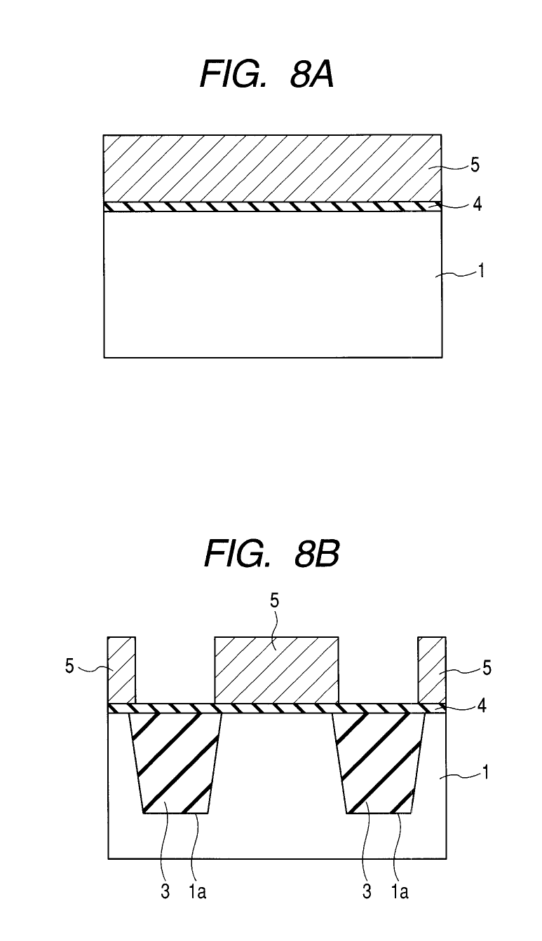

With reference to FIGS. 8(a) and 8(b), the floating gate conductive layer 5 is selectively removed by etching using a photoresist pattern (not shown) formed by photolithography as a mask. Thereby, the floating gate conductive layer 5 is patterned, and the length in the row direction of the floating gate is determined. Thereafter, the photoresist pattern (not shown) is removed.

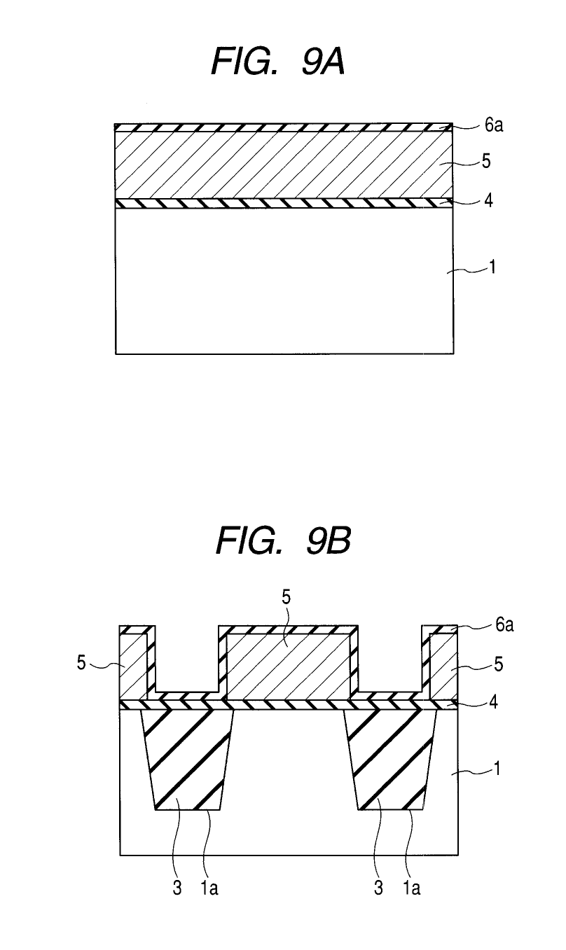

With reference to FIGS. 9(a) and 9(b), the silicon nitride film 6a is formed on the floating gate conductive layer 5 by thermal CVD, for example. This silicon nitride film 6a is controlled to a thickness of 5 nm or more.

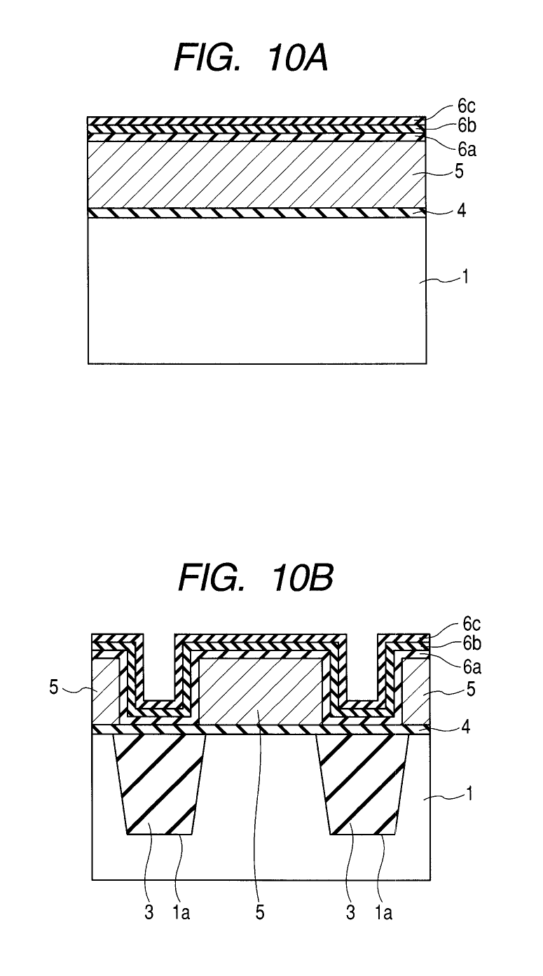

With reference to FIGS. 10(a) and 10(b), HfO2 is formed to a thickness of 10 nm as the high dielectric constant thin film 6b on the silicon nitride film 6a by thermal CVD. A silicon oxide film having a thickness of 5 nm is formed as the insulating layer 6c on the high dielectric constant thin film 6b by vacuum CVD.

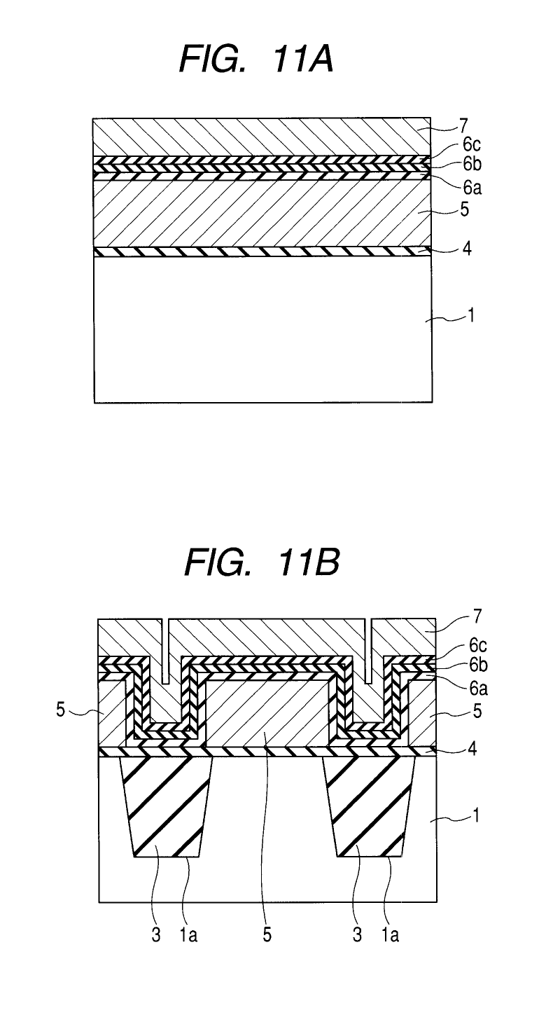

With reference to FIGS. 11(a) and 11(b), a doped polysilicon layer is formed as the control gate conductive layer 7 on the insulating layer 6c by vacuum CVD.

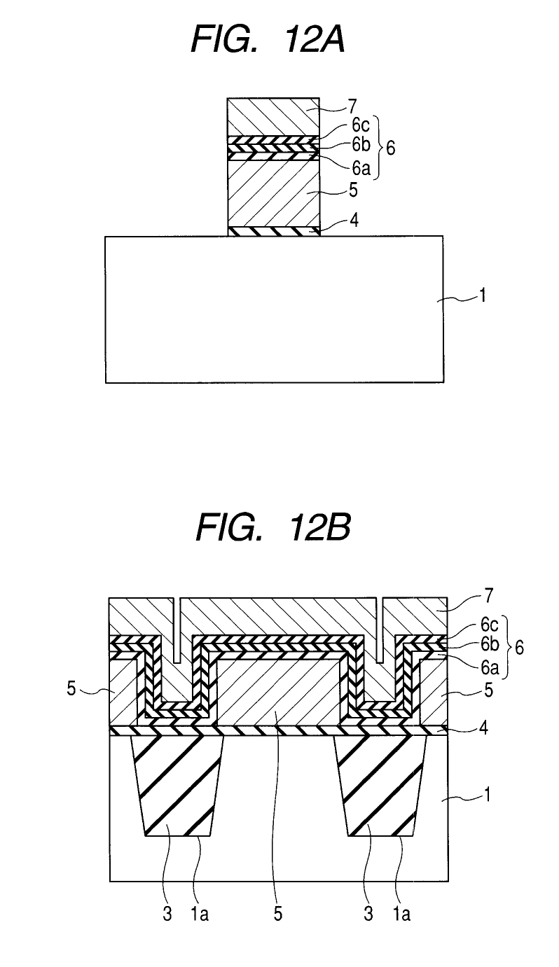

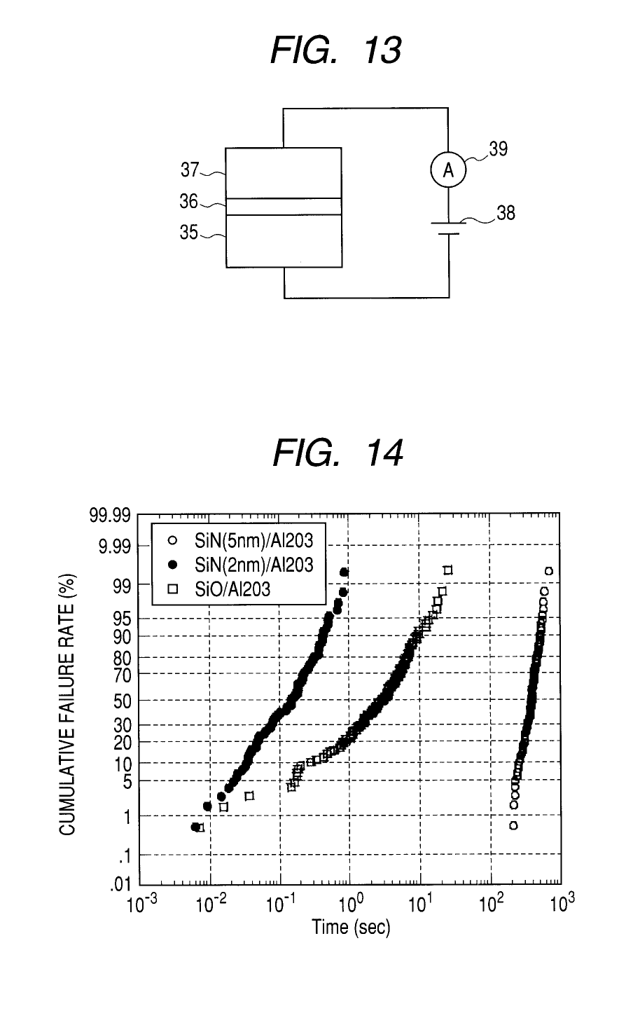

With reference to FIGS. 12(a) and 12(b), the control gate conductive layer 7, the insulating layer 6c, the high dielectric constant thin film 6b, the silicon nitride film 6a, the floating gate conductive layer 5 and the gate insulating layer 4 are removed one after another by etching using a photoresist pattern (not shown) formed over the control gate conductive layer 7 by photolithography. Thereby, a control gate electrode layer is formed from the control gate conductive layer 7 and a floating gate electrode layer is formed from the floating gate conductive layer 5 in a predetermined pattern. Thereafter, the photoresist pattern (not shown) is removed.

Subsequently, arsenide is ion injected to form an n type impurity diffusion area which will become a source/drain, and a defect formed by ion injection is repaired to manufacture the non-volatile semiconductor memory shown in FIGS. 2 to 4.

Thereafter, thermal oxidation is carried out to cover the area around the floating gate electrode layer 5, thereby forming a silicon oxide film around each memory cell. Further, an interlayer insulating layer is formed on the entire front surface, and aluminum wiring is then formed.

A description is subsequently given of studies conducted by the inventor of the present invention.

The inventor of the present invention has conducted intensive studies to obtain high dielectric strength even when a high dielectric constant thin film is used as the inter-gate insulating layer. Before this, they investigated CVS-TDDB (Constant Voltage Stress-Time Dependent Dielectric Breakdown) characteristics. For the measurement of the CVS-TDDB characteristics, as shown in FIG. 13, a lower electrode 35 and an upper electrode 37 are opposed to each other while they are insulated from each other by an insulating layer 36 and connected to a power supply 38. A leak current when a high voltage of 10 to 15 V is applied by the power supply 38 for a certain period of time and then 3 V is applied by the power supply 38 is measured by an ammeter 39. It is judged that a breakdown occurs when the current value exceeds 1 mA, for example.

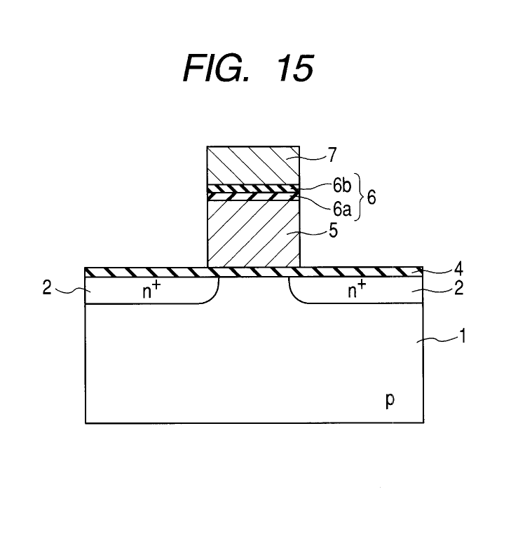

Three specimens were used for measurement: a specimen having an alumina (Al2O3) high dielectric constant thin film as the insulating layer 36 and a silicon oxide film formed between the alumina and the lower electrode 35, a specimen having a silicon nitride film (Si3N4) having a thickness of 2 nm, and a specimen having a silicon nitride film (Si3N4) having a thickness of 5 nm. The measurement results are shown in FIG. 14.

In FIG. 14, the horizontal axis shows the elapsed time and the vertical axis shows the cumulative failure rate when a time on the horizontal axis elapses (cumulative number of specimens which experienced a breakdown/total number of measured specimens). It is understood from the results of FIG. 14 that a breakdown hardly occurs in the specimen having a 5 nm-thick silicon nitride film between alumina and the lower electrode 35 and its dielectric strength is improved as compared with the specimen having a silicon oxide film between alumina and the lower electrode 35 and the specimen having a 2 nm thick silicon nitride film between alumina and the lower electrode 35.

It is understood from this that when the silicon nitride film is formed between the lower electrode (floating gate electrode layer) and the high dielectric constant thin film, dielectric strength between the lower electrode (floating gate electrode layer) and the upper electrode (control gate electrode layer) can be made more excellent than when the silicon oxide film is formed. When the thickness of the silicon nitride film between the lower electrode (floating gate electrode layer) and the high dielectric constant thin film is made 5 nm or more, dielectric strength between the lower electrode (floating gate electrode layer) and the upper electrode (control gate electrode layer) can be improved.

According to this embodiment, since the high dielectric constant thin film 6b is formed between the floating gate electrode layer 5 and the control gate electrode layer 7, capacitance between the floating gate electrode layer 5 and the control gate electrode layer 7 can be improved.

The silicon nitride film 6a is formed between the floating gate electrode layer 5 and the high dielectric constant thin film 6b. This silicon nitride film 6a has a larger band gap than that of the high dielectric constant thin film 6b. Therefore, the potential barrier between the floating gate electrode layer 5 and the inter-gate insulating layer 6 becomes high to suppress the movement of electrons accumulated in the floating gate electrode layer 5 to the inter-gate insulating layer 6. This makes it possible to control the generation of a leak current and to improve the memory retention properties of the non-volatile semiconductor memory.

Since the silicon nitride film 6a is formed between the floating gate electrode layer 5 and the high dielectric constant thin film 6b, as shown in FIG. 14, dielectric strength between the floating gate electrode layer 5 and the control gate electrode layer 7 can be made higher than when the silicon oxide film is formed between these two layers 5 and 6b.

Since the thickness of the silicon nitride film is 5 nm or more, as shown in FIG. 14, dielectric strength between the floating gate electrode layer 5 and the control gate electrode layer 7 can be improved.

The silicon nitride film 6a is formed on the floating gate electrode layer 5, and there is no useless layer between the silicon nitride film 6a and the floating gate electrode layer 5. Therefore, the interval between the floating gate electrode layer 5 and the control gate electrode layer 7 can be made small. Thereby, large capacitance between the floating gate electrode layer 5 and the control gate electrode layer 7 can be ensured.

The insulating layer 6c having a larger band gap than that of the high dielectric constant thin film is formed between the high dielectric constant thin film 6b and the control gate electrode layer 7. Therefore, the potential barrier between the control gate electrode layer 7 and the inter-gate electrode layer 6 becomes high. Therefore, the generation of a leak current between the control gate electrode layer 7 and the inter-gate electrode layer 6 can be suppressed.

To further increase capacitance between the floating gate electrode layer 5 and the control gate electrode layer 7, the insulating layer 6c may be omitted. In this case, as shown in FIG. 15, the control gate electrode layer 7 is formed on the high dielectric constant thin film 6b.

Since the constitution shown in FIG. 15 except for the above is almost the same as the constitution shown in FIGS. 2 to 4, the same elements are given the same reference symbols and their descriptions are omitted.

It should be understood that the present embodiment is illustrative and not restrictive. The scope of the invention is defined by the appended claims rather than by the description preceding them, and all changes that fall within meets and bounds of the claims, or equivalence of such meets and bounds are therefore intended to be embraced by the claims.

The present invention can be advantageously applied to a non-volatile semiconductor memory having a floating gate electrode layer and a control gate electrode layer and a manufacturing process thereof.

What is claimed is:

1. A non-volatile semiconductor memory comprising:
a substrate;
a floating gate electrode layer formed over the substrate;
a silicon nitride film formed on the floating gate electrode layer and having a thickness of 5 nm or more;
a high dielectric constant thin film formed over the silicon nitride film; and
a control gate electrode layer formed over the high dielectric constant thin film.

2. The non-volatile semiconductor memory according to claim 1, further comprising an insulating layer formed between the high dielectric constant thin film and the control gate electrode layer and having a wider band gap than that of the high dielectric constant thin film.

3. The non-volatile semiconductor memory according to claim 2, wherein the insulating layer is at least one of a silicon oxide film and a silicon nitride film.

4. The non-volatile semiconductor memory according to any one of claims 1 to 3, wherein the high dielectric constant thin film is made of at least one material selected from HfO2, Al2O3, Y2O3, MgO, Ta2O5, Bi2O3, BaMgF4, HfAlO, SrTiO3, PbTiO3, BaTiO3, BaSrTiO3, BSN, PZT and PLZT.

5. A manufacturing process of a non-volatile semiconductor memory, comprising the steps of:
forming a floating gate conductive layer over a substrate;
forming a silicon nitride film having a thickness of 5 nm or more on the floating gate conductive layer by thermal CVD;
forming a high dielectric constant thin film over the silicon nitride film; and
forming a control gate conductive layer over the high dielectric constant thin film.
